(19) United States
(12) Patent Application Publication
(10) Pub. No.: US 2025/0286316 A1
(43) Pub. Date: Sep. 11, 2025

(54) I/O UNIT AND BASE UNIT

(71) Applicant: FANUC CORPORATION, Yamanashi (JP)

(72) Inventors: Masahiro SAEKI, Yamanashi-ken (JP); Shinichi KUWAHATA, Yamanashi-ken (JP); Jens OESTERHAUS, Detmold (DE); Jan MEIER, Detmold (DE); Ralf SCHUMACHER, Lemgo (DE); Klaus PUESCHNER, Detmold (DE); Torsten DIEKMANN, Leopoldshoehe (DE)

(21) Appl. No.: 18/858,567

(22) PCT Filed: Apr. 28, 2022
(86) PCT No.: PCT/JP2022/019310

§ 371 Date: Oct. 21, 2024

(51) Int. Cl. H01R 13/629; H01R 13/22; H01R 25/14

(52) U.S. Cl. CPC H01R 13/629; H01R 13/22; H01R 25/142

(57) ABSTRACT

An I/O unit is arranged adjacent to another I/O unit along a first direction, and includes end engaging parts provided at an end section in a second direction orthogonal to the first direction; connection terminals provided on both sides of the first direction; and side engaging parts and side engaged parts provided respectively on one side and the other side of the first direction. The connection terminals are located at a position overlapping with the side engaging parts and the side engaged parts in the second direction, or on the end engaging parts side from the side engaging parts and side engaged parts.

### TECHNICAL FIELD

The present invention relates to an I/O unit, and a base unit provided in the I/O unit.

### BACKGROUND ART

JP 2018-056503 A discloses an I/O unit. According to JP 2018-056503 A, a plurality of I/O units are installed on a DIN rail.

### SUMMARY OF THE INVENTION

The I/O units each include side terminals. The side terminals are provided on both sides of the I/O unit (see also JP 2018-056503 A). Two I/O units adjacent to each other on the DIN rail are electrically connected to each other by bringing their side terminals into contact with each other.

However, each I/O unit installed on the DIN rail may be tilted with respect to another adjacent I/O unit. As a result, the side terminals of the two adjacent I/O units are separated from each other.

The present invention has the object of solving the aforementioned problem.

According to a first aspect of the present invention, there is provided an I/O unit configured to be arranged adjacent to another I/O unit along a first direction, the I/O unit comprising: an end engagement portion provided at an end portion on one side in a second direction orthogonal to the first direction, the end engagement portion being configured to engage with an installation member extending in the first direction; connection terminals provided on both sides in the first direction, and electrically connected to another I/O unit arranged adjacent to the I/O unit; a side engaging portion provided on one side in the first direction and configured to engage with another I/O unit arranged adjacent to the I/O unit on the one side; and a side engaged portion provided on another side in the first direction and configured to engage with the side engaging portion of another I/O unit arranged adjacent to the I/O unit on the other side, wherein the connection terminals provided on the both sides in the first direction are provided at positions where the connection terminals overlap the side engaging portion and the side engaged portion in the second direction, or provided closer to the end engagement portion than are the side engaging portion and the side engaged portion in the second direction.

According to a second aspect of the present invention, there is provided a base unit to which a control module configured to perform signal processing is connected in an I/0 unit configured to be arranged adjacent to another I/O unit along a first direction, the base unit comprising: an end engagement portion provided at an end portion on one side in a second direction orthogonal to the first direction, the end engagement portion being configured to engage with an installation member extending in the first direction; a mounting portion provided on another side in the second direction, the control module being inserted into the mounting portion along the second direction; connection terminals provided on both sides in the first direction, electrically connected to the control module inserted into the mounting portion, and electrically connected to another I/O unit arranged adjacent to the I/O unit; a side engaging portion provided on one side in the first direction and configured to engage with another I/O unit arranged adjacent to the I/O unit on the one side; and a side engaged portion provided on another side in the first direction and configured to engage with the side engaging portion of another I/O unit arranged adjacent to the I/O unit on the other side, wherein the connection terminals provided on the both sides in the first direction are provided at positions where the connection terminals overlap the side engaging portion and the side engaged portion in the second direction, or provided closer to the end engagement portion than are the side engaging portion and the side engaged portion in the second direction.

According to the present invention, the possibility that the connection terminals of two adjacent I/O units are separated from each other is reduced.

### BRIEF DESCRIPTION OF DRAWINGS

FIG. 1 is a perspective view of a communication system according to a reference example;

FIG. 2A is a perspective view showing a front portion and a left side portion of an I/O unit according to the reference example, and FIG. 2B is a perspective view showing a rear portion and a right side portion of the I/O unit according to the reference example;

FIG. 3 is a diagram schematically showing a state where the I/O unit is tilted with respect to an adjacent I/O unit in the reference example;

FIG. 4A is a perspective view showing a front portion and a left side portion of an I/O unit according to an embodiment, FIG. 4B is an exploded view of the I/O unit of FIG. 4A, and FIG. 4C is a perspective view showing a rear portion and a right side portion of the I/O unit of FIG. 4A;

FIG. 5A is a diagram schematically showing a plurality of I/O units arranged in a left-right direction, and FIG. 5B is a diagram schematically showing a state where one of the plurality of I/O units of FIG. 5A is tilted; and

FIG. 6 is a diagram showing an I/O unit according to a first modification.

### DETAILED DESCRIPTION OF THE INVENTION

### EMBODIMENT

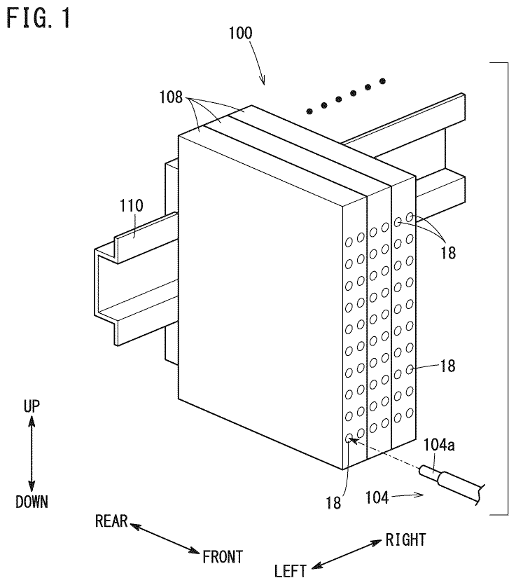

FIG. 1 is a perspective view of a communication system 100 according to a reference example.

Note that a plurality of arrows shown in each drawing indicate respective directions (front, rear, left, right, up, and down) used in the following description. A left-right direction (a first direction), a front-rear direction (a second direction), and an up-down direction (a third direction) are orthogonal to each other. The left-right direction and the front-rear direction are parallel to a horizontal plane, for example.

The communication system 100 is a system for transmitting signals between a controller and a device 104. The controller is, for example, a numerical controller that controls a machine tool. The device 104 is, for example, an actuator, a detector, or the like provided in the machine tool. The controller is not shown in the drawing. FIG. 1 shows only a part including an external terminal 104a of the device 104.

The communication system 100 includes a plurality of I/O units (input/output units) 108. The plurality of I/O units 108 are consecutively arranged on a predetermined installation member 110.

The installation member 110 is, for example, a DIN rail. The extending direction of the installation member 110 illustrated in FIG. 1 is the left-right direction. That is, the installation member 110 illustrated in FIG. 1 is long in the left-right direction.

The plurality of I/O units 108 are attached to the front portion of the installation member 110. In the illustration of FIG. 1, the arrangement direction of the plurality of I/O units 108 coincides with the extending direction of the installation member 110.

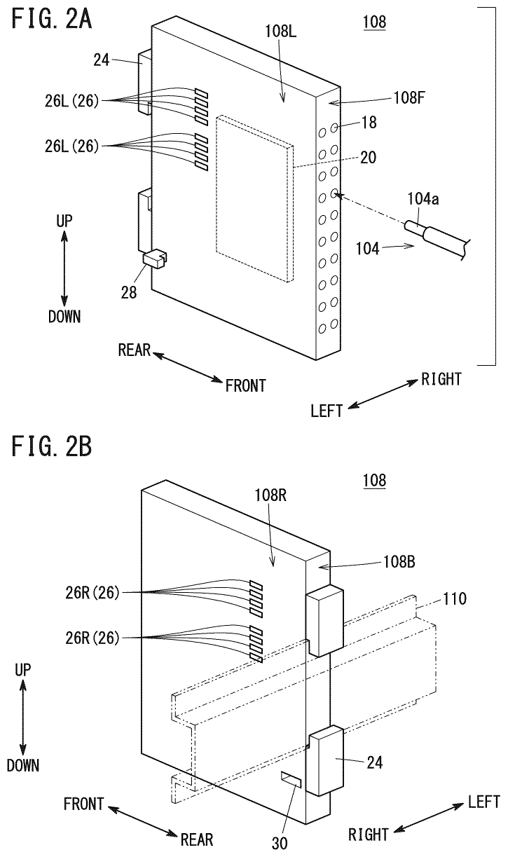

FIG. 2A is a perspective view showing a front portion 108F and a left side portion 108L of the I/O unit 108 according to the reference example. FIG. 2B is a perspective view showing a rear portion 108B and a right side portion 108R of the I/O unit 108 according to the reference example.

The I/O unit 108 includes an insertion-receiving portion 18, a control module 20, an end engagement portion 24, and a plurality of connection terminals 26.

The insertion-receiving portion 18 is provided in the front portion 108F of the I/O unit 108. The external terminal 104a can be connected to the insertion-receiving portion 18.

The number of the insertion-receiving portions 18 provided in the I/O unit 108 is not particularly limited. Each I/O unit 108 illustrated in FIGS. 1, 2A, and the like is provide with a plurality of the insertion-receiving portions 18. In this case, each illustrated I/O unit 108 may be connected to a plurality of the devices 104 according to the number of the provided insertion-receiving portions 18.

The control module 20 is a module that performs necessary processing in the I/O unit 108. The control module 20 is accommodated in the I/O unit 108. The control module 20 includes, for example, a circuit board on which a predetermined electric circuit is formed. The electric circuit includes, for example, a control integrated circuit (IC).

The control module 20 is electrically connected to the external terminal 104a via the insertion-receiving portion 18. Consequently, the control module 20 can communicate with the device 104 via the insertion-receiving portion 18. In a case where a plurality of the devices 104 are connected to the I/O unit 108, the control module 20 communicates with the plurality of devices 104.

The end engagement portion 24 is provided at the rear portion (an end portion) 108B of the I/O unit 108. The end engagement portion 24 is provided to engage with the installation member 110. For example, the end engagement portion 24 includes a claw that engages with a part of the installation member 110. The I/O unit 108 is installed on the installation member 110 by the end engagement portion 24 engaging with the installation member 110.

The plurality of connection terminals 26 are disposed on each of the left side portion 108L and the right side portion 108R of the I/O unit 108. The plurality of connection terminals 26 are electrically connected to the control module 20. Therefore, the device 104 is electrically connected to the plurality of connection terminals 26 via the control module 20.

In the following description, the connection terminals 26 disposed on the left side portion 108L are also referred to as connection terminals 26L. Further, the connection terminals 26 disposed on the right side portion 108R are also referred to as connection terminals 26R.

In a case where two I/O units 108 are adjacent to each other in the left-right direction, the plurality of connection terminals 26L of the I/O unit 108 disposed on the right side are connected to the plurality of connection terminals 26R of the I/O unit 108 disposed on the left side. Consequently, the control module 20 of the I/O unit 108 disposed on the right side is communicably connected to the control module 20 of the I/O unit 108 disposed on the left side.

The two electrically connected control modules 20 can communicate with each other.

In this instance, according to the illustration of FIG. 1, the plurality of I/O units 108 are consecutively arranged in the left-right direction. In this case, the control modules 20 of all the I/O units 108 are communicably connected to each other via the plurality of connection terminals 26 provided in each of the I/O units 108.

The control module 20 of the I/O unit 108 disposed on the leftmost side or the rightmost side among the plurality of I/O units 108 is electrically connected to the controller described above. As a result, the controller and the device 104 are electrically connected to each other via at least one I/O unit 108.

According to the communication system 100 described above, the controller can communicate with all the devices 104 connected to the I/O units 108.

However, in the two I/O units 108 adjacent to each other in the left-right direction, if the plurality of connection terminals 26L of the I/O unit 108 disposed on the right side and the plurality of connection terminals 26R of the I/O unit 108 disposed on the left side are separated from each other, the above-described communication cannot be performed.

In view of this, it is preferable that the I/O unit 108 further includes a coupling mechanism for mechanically coupling the I/O unit 108 to another I/O unit 108 adjacent thereto in the left-right direction. Therefore, the I/O unit 108 further including a side engaging portion 28 and a side engaged portion 30 is considered.

The side engaging portion 28 and the side engaged portion 30 are disposed on different sides of the I/O unit 108. For example, the side engaging portion 28 is disposed on the left side portion 108L (FIG. 2A). In this case, the side engaged portion 30 is disposed on the right side portion 108R (FIG. 2B).

The side engaging portion 28 includes, for example, a claw portion. On the other hand, the side engaged portion 30 includes, for example, a groove portion. In the two I/O units 108 adjacent to each other in the left-right direction, the side engaging portion 28 of the I/O unit 108 disposed on the right side engages with the side engaged portion 30 of the I/O unit 108 disposed on the left side.

Consequently, in the two I/O units 108 adjacent to each other in the left-right direction, it is expected that the plurality of connection terminals 26L of the I/O unit 108 disposed on the right side and the plurality of connection terminals 26R of the I/O unit 108 disposed on the left side can be prevented from being separated from each other.

Further, the side engaging portion 28 and the side engaged portion 30 serve to mechanically couple the I/O unit 108 to another I/O unit 108, whereby it becomes unnecessary for each connection terminal 26 to have a structure for mechanical coupling to another I/O unit 108. This can simplify the structure of each connection terminal 26.

However, the I/O unit 108 described above has room for further improvement as described below. Specifically, in a case where the plurality of I/O units 108 are coupled to each other by using the side engaging portions 28 and the side engaged portions 30, at least one I/O unit 108 may be tilted with respect to the adjacent I/O unit 108. This may cause communication between the plurality of I/O units 108 to be cut off.

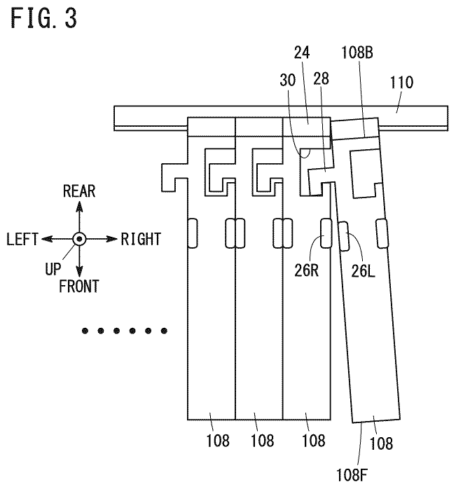

FIG. 3 is a diagram schematically showing a state where the I/O unit 108 is tilted with respect to the adjacent I/O unit 108 in the reference example.

For example, among the plurality of I/O units 108 illustrated in FIG. 3, the I/O unit 108 disposed on the rightmost side is tilted with respect to the adjacent I/O unit 108. Consequently, the connection terminals 26L of the I/O unit 108 disposed on the rightmost side and the connection terminals 26R of the adjacent I/O unit 108 are separated from each other. As a result, the I/O unit 108 disposed on the rightmost side cannot communicate with all the I/O units 108 disposed on the left side of this I/O unit 108.

The reason why one of the two adjacent I/O units 108 tilts with respect to the other is that the engagement between the side engaging portion 28 and the side engaged portion 30 is loose. Specifically, even when the side engaging portion 28 and the side engaged portion 30 engage with each other, a gap is left between the side engaging portion 28 and the side engaged portion 30. As a result, even after the side engaging portion 28 and the side engaged portion 30 have engaged with each other, one of the two adjacent I/O units 108 can be displaced with respect to the other. The tilting described above occurs as a result of one of the two adjacent I/O units 108 being displaced with respect to the other.

Several methods for preventing one of the two adjacent I/O units 108 from being tilted with respect to the other are considered. For example, eliminating the gap between the side engaging portion 28 and the side engaged portion 30 is considered as a first method. That is, it is considered to design the shapes of the side engaging portion 28 and the side engaged portion 30 so that no gap is formed when the side engaging portion 28 and the side engaged portion 30 engage with each other.

However, in a case where the first method is employed, there is a concern that the operation of engaging the side engaging portion 28 and the side engaged portion 30 will be more difficult than necessary. In addition, in a case where the first method is employed, the work of disengaging the side engaging portion 28 and side engaged portion 30 that have been engaged also becomes difficult. Further, the first method is not practical because, at least for the side engaging portion 28 and the side engaged portion 30, it does not allow any dimensional error that occurs during actual manufacturing or any wear during use. Therefore, the first method is not preferable as a solution for preventing one of the two adjacent I/O units 108 from being tilted with respect to the other.

Tightening together the two adjacent I/O units 108 using a coupling member such as a screw is considered as a second method. In this case, by the coupling member tightening the two I/O units 108 with a force as strong as possible, it may be possible to prevent one of the two adjacent I/O units 108 from being tilted with respect to the other.

However, in a case where the second method is employed, the operation of tightening together the plurality of I/O units 108 becomes a burden on an operator. The burden increases as the number of the I/O units 108 provided in the communication system 100 increases. Therefore, also the second method is not preferable in consideration of the labor of the operator.

Based on the above, an I/O unit 10 according to an embodiment will be described below. However, explanations overlapping with those of the above-described reference example will be omitted as much as possible in the following description. Elements that have been described in the reference example are denoted by the same reference numerals as in the reference example unless otherwise specified.

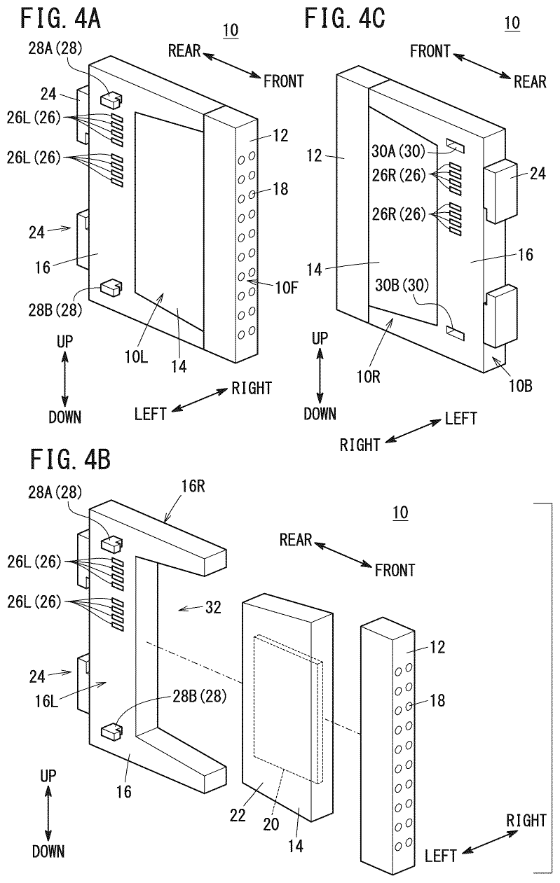

FIG. 4A is a perspective view showing a front portion 10F and a left side portion 10L of the I/O unit 10 according to the embodiment. FIG. 4B is an exploded view of the I/O unit 10 of FIG. 4A. FIG. 4C is a perspective view showing a rear portion 10B and a right side portion 10R of the I/O unit 10 of FIG. 4A.

The I/O unit 10 is preferably divisible into a connector unit 12, a communication processing unit 14, and a base unit 16, which will be described below.

The connector unit 12 is a part including the front portion 10F of the I/O unit 10. The connector unit 12 is disposed forward of the communication processing unit 14.

The connector unit 12 includes an insertion-receiving portion 18. The insertion-receiving portion 18 is disposed on the front portion 10F. The number of the insertion-receiving portions 18 provided in the connector unit 12 is not particularly limited. The connector unit 12 illustrated in FIG. 4A and the like includes a plurality of the insertion-receiving portions 18.

The communication processing unit 14 includes a control module 20 and a housing 22. The housing 22 is a casing that accommodates the control module 20.

The connector unit 12 is coupled to the communication processing unit 14 from the front side of the communication processing unit 14 toward the rear side. In a case where the connector unit 12 and the communication processing unit 14 are coupled to each other, a device 104 connected to the insertion-receiving portion 18 of the connector unit 12 is electrically connected to the control module 20 of the communication processing unit 14.

Therefore, in a case where the connector unit 12 and the communication processing unit 14 are coupled to each other, the device 104 connected to the insertion-receiving portion 18 of the connector unit 12 and the control module 20 of the communication processing unit 14 can communicate with each other.

The base unit 16 is a part including the rear portion (an end portion) 10B of the I/O unit 10. The base unit 16 is disposed rearward of the communication processing unit 14. The base unit 16 includes an end engagement portion 24, a plurality of connection terminals 26, a side engaging portion 28, a side engaged portion 30, and a mounting portion 32.

The end engagement portion 24 is provided at the rear portion 10B. Since the I/O unit 10 includes the end engagement portion 24, the I/O unit 10 can be installed on an installation member 110.

However, in the present embodiment, the end engagement portion 24 may be omitted. That is, the plurality of I/O units 10 may be lined up without being installed on the installation member 110.

The plurality of connection terminals 26 are disposed on each of a left side portion 16L and a right side portion 16R of the base unit 16. In the following description, the plurality of connection terminals 26 arranged on the left side portion 16L are also referred to as connection terminals 26L. Further, the connection terminals 26 disposed on the right side portion 16R are also referred to as connection terminals 26R.

Note that the left side portion 16L of the base unit 16 is included in the left side portion 10L of the I/O unit 10. The right side portion 16R of the base unit 16 is included in the right side portion 10R of the I/O unit 10.

A part of each of the plurality of connection terminals 26L is exposed to the outside of the base unit 16 on the left side portion 16L. Further, a part of each of the plurality of connection terminals 26R is exposed to the outside of the base unit 16 on the right side portion 16R. The plurality of connection terminals 26L and the plurality of connection terminals 26R are arranged substantially symmetrically in the left-right direction.

The plurality of connection terminals 26L can be connected to the plurality of connection terminals 26R provided in another I/O unit 10 installed on the left side of the I/O unit 10. Similarly, the plurality of connection terminals 26R can be connected to the plurality of connection terminals 26L provided in another I/O unit 10 installed on the right side of the I/O unit 10.

The mounting portion 32 is provided at a front portion of the base unit 16. The mounting portion 32 is a portion of the base unit 16 where the communication processing unit 14 is mounted (inserted). The communication processing unit 14 is mounted on the mounting portion 32 from the front side of the base unit 16 toward the rear side, for example.

The communication processing unit 14 is mounted on the mounting portion 32, whereby the communication processing unit 14 and the base unit 16 are coupled to each other. The plurality of connection terminals 26 are electrically connected to the control module 20 of the communication processing unit 14.

The side engaging portion 28 is disposed on the left side portion 16L. In this instance, the side engaging portion 28 is disposed at substantially the same position as the plurality of connection terminals 26L or forward of the plurality of connection terminals 26L in the front-rear direction. The substantially same position as the plurality of connection terminals 26L in the front-rear direction is a position where the side engaging portion 28 overlaps the plurality of connection terminals 26L when viewed in the up-down direction.

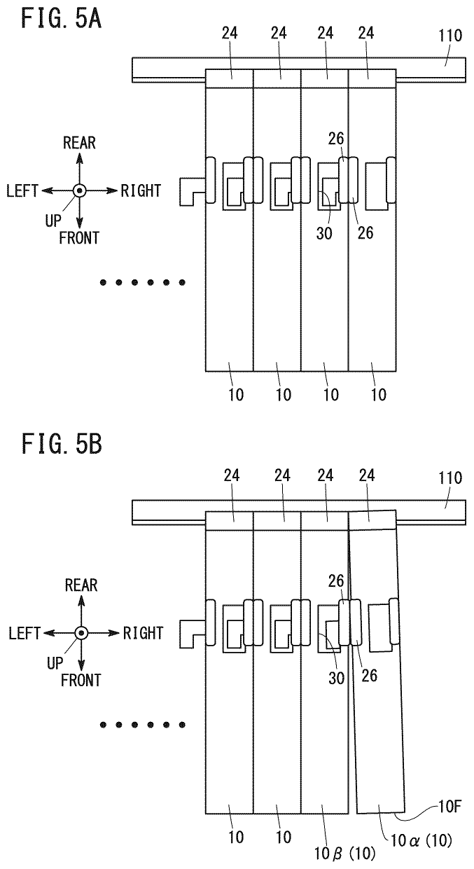

The side engaging portion 28 of the present embodiment is disposed at substantially the same position as the plurality of connection terminals 26L in the front-rear direction (see also FIG. 5A). In this case, the side engaging portion 28 is disposed at a different position from the plurality of connection terminals 26L in the up-down direction.

The base unit 16 preferably includes a plurality of the side engaging portions 28 (28A, 28B). The base unit 16 of the present embodiment includes a first side engaging portion 28A and a second side engaging portion 28B. The first side engaging portion 28A is disposed above the plurality of connection terminals 26L. The second side engaging portion 28B is disposed below the plurality of connection terminals 26L.

The side engaged portion 30 is disposed on the right side portion 16R. In this instance, the side engaged portion 30 is disposed at substantially the same position as the plurality of connection terminals 26R or forward of the plurality of connection terminals 26R in the front-rear direction, so as to be engageable with the side engaging portion 28 of another I/O unit 10 installed on the right side of the I/O unit 10. The substantially same position as the plurality of connection terminals 26R in the front-rear direction is a position where the side engaged portion 30 overlaps the plurality of connection terminals 26R when viewed in the up-down direction.

The side engaged portion 30 of the present embodiment is disposed at substantially the same position as the plurality of connection terminals 26R in the front-rear direction. In this case, the side engaged portion 30 is disposed at a different position from the plurality of connection terminals 26R in the up-down direction (see also FIG. 4C).

The number of the side engaged portions 30 provided on the base unit 16 is the same as the number of the side engaging portions 28 provided on the base unit 16. For example, in the case of the present embodiment, the base unit 16 includes two side engaged portions 30 (30A, 30B) (see also FIG. 4C). A first side engaged portion 30A is disposed above the plurality of connection terminals 26R. A second side engaged portion 30B is disposed below the plurality of connection terminals 26R.

According to the present embodiment, in a case where one of two I/O units 10 adjacent to each other in the left-right direction is tilted with respect to the other, the possibility that the communication between the control modules 20 of the two I/O units 10 is cut off is reduced. The reason is as follows.

FIG. 5A is a diagram schematically showing a plurality of the I/O units 10 arranged in the left-right direction.

The I/O unit 10 and other I/O units 10 are installed so as to be arranged in the left-right direction. The control modules 20 of two I/O units 10 adjacent to each other in the left-right direction are communicably connected to each other via the respective plurality of connection terminals 26.

The number of the I/O units 10 to be arranged is not particularly limited. In a case where three or more I/O units 10 are arranged in the left-right direction, the control modules 20 of all the I/O units 10 are communicably connected to each other via the respective plurality of connection terminals 26.

FIG. 5B is a diagram schematically showing a state where one of the plurality of I/O units 10 of FIG. 5A is tilted.

For example, in the illustration of FIG. 5B, the plurality of I/O units 10 arranged in the left-right direction include an I/O unit 10α disposed on the rightmost side, and an I/O unit 10β disposed on the immediate left side of the I/O unit 10α.

The I/O unit 10α is titled with respect to the I/O unit 10B. Consequently, a part of the left side portion of the I/O unit 10α and a part of the right side portion of the I/O unit 10β are separated from each other in the left-right direction.

However, the side engaging portions 28 of the I/O unit 10α and the side engaged portions 30 of the I/O unit 10β have been engaged with each other. In this case, the I/O unit 10α is tilted about the side engaging portions 28 of the I/O unit 10α and the side engaged portions 30 of the I/O unit 10β.

Therefore, the side engaging portions 28 of the I/O unit 10α are not largely separated in the right-left direction from the side engaged portions 30 of the I/O unit 10β. In this case, also the plurality of connection terminals 26L disposed at substantially the same position as the side engaging portions 28 of the I/O unit 10α in the front-rear direction are not largely separated in the left-right direction from the plurality of connection terminals 26R disposed at substantially the same position as the side engaged portions 30 of the I/O unit 10β in the front-rear direction.

In this manner, according to the present embodiment, the plurality of connection terminals 26L of the I/O unit 10α and the plurality of connection terminals 26R of the I/O unit 10β are not separated from each other. Therefore, the communication between the control module 20 of the I/O unit 10α and the control module 20 of the I/O unit 10β is not cut off.

Further, according to the present embodiment, two side engaging portions 28 and two side engaged portions 30 are disposed so as to sandwich the plurality of connection terminals 26L of the I/O unit 10α and the plurality of connection terminals 26R of the I/O unit 10β. This restricts more strongly the separation between the plurality of connection terminals 26L of the I/O unit 10α and the plurality of connection terminals 26R of the I/O unit 10β.

Moreover, according to the present embodiment, the I/O unit 10 can be divided into a plurality of units. Specifically, the I/O unit 10 can be divided into the connector unit 12 having a function of connecting to the device 104, the communication processing unit 14 having a function of performing communication processing, and the base unit 16 having a function of connecting to another I/O unit 10. As a result, the operator can perform maintenance on each of the connector unit 12, the communication processing unit 14, and the base unit 16, for example.

### Modifications

Modifications of the above-described embodiment will be described below. However, explanations overlapping with those of the above-described embodiment will be omitted as much as possible in the following description. Elements that have been described in the above-described embodiment are denoted by the same reference numerals as in the above-described embodiment unless otherwise specified.

### (Modification 1)

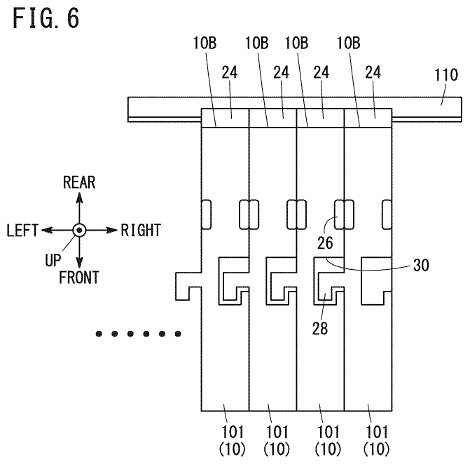

FIG. 6 is a diagram showing an I/O unit 101 (10) according to a first modification. Note that this modification is based on the premise that the end engagement portion 24 is provided at the rear portion 10B of the I/O unit 101.

The side engaging portion 28 and the side engaged portion 30 may be disposed forward of the plurality of connection terminals 26. The side engaging portion 28 or the side engaged portion 30 engages with another I/O unit 101, thereby restricting the large separation in the left-right direction between the side engaging portion 28 or the side engaged portion 30, and the end engagement portion 24 engaged with the installation member 110.

On the other hand, the end engagement portion 24 engages with the installation member 110, thereby restricting the large separation in the left-right direction between the end engagement portion 24 and the side engaging portion 28 or the side engaged portion 30 engaged with another I/O unit 101.

As a result, the positional displacement in the left-right direction of the plurality of connection terminals 26 sandwiched between the side engaging portion 28 (the side engaged portion 30) and the end engagement portion 24 in the front-rear direction is strongly restricted. This reduces the possibility that the connection terminals 26 of the two adjacent I/O units 101 are separated from each other.

### (Modification 2)

The side engaged portion 30 may be provided on the left side portion 16L. In this case, the side engaging portion 28 is provided on the right side portion 16R.

Note that both the side engaging portion 28 and the side engaged portion 30 may be provided on each of the left side portion 16L and the right side portion 16R. For example, the side engaging portion 28 is provided above the plurality of connection terminals 26L on the left side portion 16L, and the side engaged portion 30 is provided below the plurality of connection terminals 26L on the left side portion 16L. In this case, the side engaged portion 30 is provided above the plurality of connection terminals 26R on the right side portion 16R, and the side engaging portion 28 is provided below the plurality of connection terminals 26R on the right side portion 16R.

### (Modification 3)

The connection terminals 26, the side engaging portion 28, and the side engaged portion 30 may be provided in the communication processing unit 14 or the connector unit 12.

### (Combination of Plurality of Modifications)

The modifications described above may be appropriately combined within a range in which no contradiction occurs.

### Inventions Obtained from Embodiment

Hereinafter, the inventions that can be grasped from the above-described embodiment and modifications will be described.

### <First Aspect of Invention>

A first aspect of the present invention is the I/O unit (10) configured to be arranged adjacent to another I/O unit (10) along a first direction, the I/O unit including: the end engagement portion (24) provided at the end portion (10B) on one side in a second direction orthogonal to the first direction, the end engagement portion being configured to engage with the installation member (110) extending in the first direction; the connection terminals (26) provided on both sides in the first direction, and electrically connected to another I/O unit (10) arranged adjacent to the I/O unit; the side engaging portion (28) provided on one side in the first direction and configured to engage with another I/O unit (10) arranged adjacent to the I/O unit on the one side; and the side engaged portion (30) provided on another side in the first direction and configured to engage with the side engaging portion of another I/O unit (10) arranged adjacent to the I/O unit on the other side, wherein the connection terminals provided on the both sides in the first direction are provided at positions where the connection terminals overlap the side engaging portion and the side engaged portion in the second direction, or provided closer to the end engagement portion than are the side engaging portion and the side engaged portion in the second direction.

This reduces the possibility that the connection terminals of the two adjacent I/O units are separated from each other.

The side engaging portion may include the first side engaging portion (28A) and the second side engaging portion (28B) that are arranged so as to sandwich, in a third direction, the connection terminal provided on the one side in the first direction, the third direction being orthogonal to the first direction and the second direction, and the side engaged portion may include the first side engaged portion (30A) and the second side engaged portion (30B) that are arranged so as to sandwich, in the third direction, the connection terminal provided on the other side in the first direction. This further reduces the possibility that the connection terminals of the two adjacent I/O units are separated from each other.

### <Second Aspect of Invention>

A second aspect of the present invention is the base unit (16) to which the control module (20) configured to perform signal processing is connected in the I/O unit (10) configured to be arranged adjacent to another I/O unit (10) along a first direction, the base unit including: the end engagement portion (24) provided at the end portion (10B) on one side in a second direction orthogonal to the first direction, the end engagement portion being configured to engage with the installation member (110) extending in the first direction; the mounting portion (32) provided on another side in the second direction, the control module being inserted into the mounting portion along the second direction; the connection terminals (26) provided on both sides in the first direction, electrically connected to the control module inserted into the mounting portion, and electrically connected to another I/O unit (10) arranged adjacent to the I/O unit; the side engaging portion (28) provided on one side in the first direction and configured to engage with another I/O unit (10) arranged adjacent to the I/O unit on the one side; and the side engaged portion (30) provided on another side in the first direction and configured to engage with the side engaging portion of another I/O unit (10) arranged adjacent to the I/O unit on the other side, wherein the connection terminals provided on the both sides in the first direction are provided at positions where the connection terminals overlap the side engaging portion and the side engaged portion in the second direction, or provided closer to the end engagement portion than are the side engaging portion and the side engaged portion in the second direction.

This reduces the possibility that the connection terminals of the two adjacent I/O units are separated from each other.

### REFERENCE SIGNS LIST

10, 101: I/O unit
16: base unit
18: insertion-receiving portion
20: control module
24: end engagement portion
26, 26L, 26R: connection terminal
28: side engaging portion
30: side engaged portion
110: installation member

1. An I/O unit configured to be arranged adjacent to another I/O unit along a first direction, the I/O unit comprising:
an end engagement portion provided at an end portion on one side in a second direction orthogonal to the first direction, the end engagement portion being configured to engage with an installation member extending in the first direction;
connection terminals provided on both sides in the first direction, and electrically connected to another I/O unit arranged adjacent to the I/O unit;
a side engaging portion provided on one side in the first direction and configured to engage with another I/O unit arranged adjacent to the I/O unit on the one side; and
a side engaged portion provided on another side in the first direction and configured to engage with the side engaging portion of another I/O unit arranged adjacent to the I/O unit on the other side,
wherein the connection terminals provided on the both sides in the first direction are provided at positions where the connection terminals overlap the side engaging portion and the side engaged portion in the second direction, or provided closer to the end engagement portion than are the side engaging portion and the side engaged portion in the second direction.

2. The I/O unit according to claim 1, wherein
the side engaging portion includes a first side engaging portion and a second side engaging portion that are arranged so as to sandwich, in a third direction, the connection terminal provided on the one side in the first direction, the third direction being orthogonal to the first direction and the second direction, and
the side engaged portion includes a first side engaged portion and a second side engaged portion that are arranged so as to sandwich, in the third direction, the connection terminal provided on the other side in the first direction.

3. A base unit to which a control module configured to perform signal processing is connected in an I/O unit configured to be arranged adjacent to another I/O unit along a first direction, the base unit comprising:
an end engagement portion provided at an end portion on one side in a second direction orthogonal to the first direction, the end engagement portion being configured to engage with an installation member extending in the first direction;
a mounting portion provided on another side in the second direction, the control module being inserted into the mounting portion along the second direction;
connection terminals provided on both sides in the first direction, electrically connected to the control module inserted into the mounting portion, and electrically connected to another I/O unit arranged adjacent to the I/O unit;
a side engaging portion provided on one side in the first direction and configured to engage with another I/O unit arranged adjacent to the I/O unit on the one side; and
a side engaged portion provided on another side in the first direction and configured to engage with the side engaging portion of another I/O unit arranged adjacent to the I/O unit on the other side,
wherein the connection terminals provided on the both sides in the first direction are provided at positions where the connection terminals overlap the side engaging portion and the side engaged portion in the second direction, or provided closer to the end engagement portion than are the side engaging portion and the side engaged portion in the second direction.
